(19) United States
(12) Patent Application Publication
(10) Pub. No.: US 2024/0027554 A1
(43) Pub. Date: Jan. 25, 2024

(54) METHOD AND SYSTEM FOR USING FITTED RELAXATION DATA TO IMPROVE A PRODUCT

(71) Applicant: Northwestern University, Evanston, IL (US)

(72) Inventors: Matthew A. Grayson, Evanston, IL (US); Jiajun Luo, Jersey City, NJ (US); Can Aygen, Chicago, IL (US)

(21) Appl. No.: 18/224,292

(22) Filed: Jul. 20, 2023

Related U.S. Application Data
(60) Provisional application No. 63/368,951, filed on Jul. 20, 2022.

(51) Int. Cl. G01R 33/44

(52) U.S. Cl. CPC G01R 33/448

(57) ABSTRACT

A system to improve a product based on a relaxation response includes a memory configured to store relaxation response data of a sample. The relaxation response data includes time data and amplitude data. A processor is operatively coupled to the memory and configured to convert the relaxation response data to linear-amplitude versus log-time data. The processor also performs a least-squares fit of the converted relaxation response data to a heavy-tail function to determine one or more fit parameter values. The processor also updates a design for the sample based at least in part on the one or more fit parameter values.

### CROSS-REFERENCE TO RELATED APPLICATION

The present application claims the priority benefit of U.S. Provisional Patent App. No. 63/368,951 filed on Jul. 20, 2022, the entire disclosure of which is incorporated by reference herein.

### STATEMENT REGARDING FEDERALLY SPONSORED RESEARCH

This invention was made with government support under grant number CCSS-1912694 awarded by the National Science Foundation. The government has certain rights in this invention.

### BACKGROUND

In physics and other scientific fields, relaxation generally refers to the return of a disturbed system back to equilibrium. The amount of time that it takes a system to relax, changes (over a period of time) to the amount of time that it takes the system to relax, the extent to which the system is able to relax, etc. can provide helpful information regarding attributes of the system.

### SUMMARY

An illustrative system to improve a product based on a relaxation response includes a memory configured to store relaxation response data of a sample. The relaxation response data includes time data and amplitude data. A processor is operatively coupled to the memory and configured to convert the relaxation response data to linear-amplitude versus log-time data. The processor also performs a least-squares fit of the converted relaxation response data to a heavy-tail function to determine one or more fit parameter values. The processor also updates a design for the sample based at least in part on the one or more fit parameter values.

In one embodiment, the processor is configured to determine an offset parameter for the relaxation response data. In such an embodiment, the processor can determine a mean value of the relaxation response data and shift the relaxation response data relative to the mean value to create a dataset that has a zero mean value. The offset parameter is based on the created dataset. In another embodiment, the processor is configured to generate an error estimate for each of the one or more fit parameter values. To generate the error estimate of a fit parameter, the processor transforms the fit parameter to a space in which variance of a fit of the fit parameter is quadratic. The processor can also be configured to generate a confidence interval for each of the one or more fit parameter values based at least in part on the error estimate. In one embodiment, the processor applies a Hessian analysis function to the error estimate to generate the confidence interval.

The processor can also be configured to generate a report that includes the one or more fit parameter values and one or more confidence intervals associated with the one or more fit parameter values. In an illustrative embodiment, the one or more fit parameter values includes a value of a time scale of relaxation of the sample. In another embodiment, the one or more fit parameter values includes a value of an amplitude of relaxation of the sample. In another embodiment, the one or more fit parameter values includes a value of a molecularity ratio of an initial minority concentration of the sample to a majority concentration of the sample. In another embodiment, the one or more fit parameter values includes a value of an anomalous diffusion exponent for the sample. In one embodiment, the system includes an excitation device that excites the sample such that the sample exhibits the relaxation response that is a source of the relaxation response data.

An illustrative method includes storing, in a memory of a computing system, relaxation response data of a sample, where the relaxation response data includes time data and amplitude data. The method also includes converting, by a processor of the computing system, the relaxation response data to linear-amplitude versus log-time data. The method also includes performing, by the processor, a least-squares fit of the converted relaxation response data to a heavy-tail function to determine one or more fit parameter values. The method further includes updating a design for the sample based at least in part on the one or more fit parameter values.

In one embodiment, the method includes determining, by the processor, a mean value of the relaxation response data and shifting the relaxation response data relative to the mean value to create a dataset that has a zero mean value. In such an embodiment, the method includes determining an offset parameter for the relaxation response data based on the created dataset. In another embodiment, the method includes generating, by the processor, an error estimate for each of the one or more fit parameter values. The method can also include generating, by the processor, a confidence interval for each of the one or more fit parameter values based at least in part on the error estimate. The method can further include applying, by the processor, a Hessian analysis function to the error estimate to generate the confidence interval. In another embodiment, the method includes generating, by the processor, a report that includes the one or more fit parameter values and one or more confidence intervals associated with the one or more fit parameter values. The method can also include exciting, by an excitation device in communication with the computing system, the sample such that the sample exhibits a relaxation response that is a source of the relaxation response data.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 is a flow diagram depicting operations performed to analyze a system and generate an updated system based on determined fit parameters and associated confidence intervals in accordance with an illustrative embodiment.

FIG. 2 is a block diagram of a computing system 200 that uses relaxation data to improve a product in accordance with an illustrative embodiment.

### DETAILED DESCRIPTION

Many physical phenomena are understood by exciting an experimental system with a pulse or steady-state excitation and measuring the relaxation response, such as photoluminescence of fluorophore biomarkers in living cells, voltage switching of organic semiconductor transistor channels, stress relaxation in polymers, susceptibility relaxation in glassy systems, the luminescence lifetime of organic light emitting diodes (LEDs), etc. Without a proper mathematical description of the form of the experimental relaxation, the underlying characterization can easily be misinterpreted, impeding technological progress. For this reason, instrumentation companies rely on the latest in mathematical methods to be able to properly fit relaxation curves so that the experimental hardware can have the greatest benefit for the user.

Described herein are methods and systems for analysis that interprets experimental data in such a way to accurately fit a newly identified mathematical model, which can be used to create new products/systems and improve existing products/systems. Additionally, the methods and systems generate error estimates of each fit parameter. The proposed methods and systems allow for physical insights to be gleaned from the underlying meaning of each of the individual parameters. Additionally, the proposed methods and systems also provide a confidence interval for each parameter such that, for example, a low-confidence parameter value is not overinterpreted.

The proposed methods and systems can be used with respect to any experimental measurement that studies transient relaxations. For example, they can be used in any field of engineering or science. The fit analysis is proposed to achieve superior fits with fewer fit parameters than standard fit methods. The methods have applications in the fields of biology, chemistry, electronics, physics, geology, medicine, gerontology, etc. In an illustrative embodiment, the proposed methods and systems can be used to fit data from biology/biomedical experiments (e.g., photoluminescence of biomarkers in cells, dielectric response of biological tissues, etc.), mechanical experiments in polymers and composites (e.g., stress relaxation, creep, etc.), susceptibility responses in glassy systems (e.g., relaxation of dielectric susceptibility of glasses, relaxation of magnetic susceptibility in spin glasses, relaxation of magnetic field transients in pinned flux lines of superconductors, etc.), etc.

In another illustrative embodiment, the proposed methods and systems can be used to properly analyze data in linear amplitude versus log time, and analyze the proper physical parameter, rather than mistakenly fitting the derivative of the physically relevant parameter. Additionally, the proposed methods and systems use a novel analysis equation which is referred to as a heavy-tail relaxation equation to fit to the data, containing 4 fit parameters in one embodiment, plus a background offset. The proposed techniques utilize one universal function to fit all behaviors, rather than requiring the user to objectively guess at various fit expressions. Additionally, the proposed techniques can be used to output confidence intervals for each of the fit parameters to allow proper interpretation of the accuracy of the fit.

Experimental measurements of time-dependent relaxations frequently do not follow a simple exponential decay. In traditional systems, when a simple exponential fails, the standard response is to fit to an empirical bi-exponential, or multi-exponential, etc. until the desired level of accuracy is achieved, adding two fit parameters for every exponential fit added (a time constant and an amplitude). However, based on the physics of diffusion-limited second order reactions, anomalous diffusion, and continuous-time random walk theory, a more universal fit curve can be generated which is observed to fit the data with superior accuracy and fewer fit parameters. The method has several novel elements (described in more detail below), including proper identification of the physical parameter of interest, derivation of the generalized heavy-tail fit, determination of the universal applicability of the fit, and identification of confidence intervals for each parameter.

An important aspect of the proposed analysis is to properly identify the physical parameters of interest. Whereas standard treatments fit data in log-amplitude and linear-time, the proposed method fits data in linear-amplitude and log-time. This is important since the identification of a characteristic time scale is not necessarily possible to identify in linear-time of a log-linear plot, whereas the characteristic time scale is trivially associated with the inflection point in log-time in a linear-log plot. Further, whereas some experimental phenomena such as photoluminescence are often fit directly, the analysis here associates photoluminescence with the time derivative of the underlying physical parameter of interest, namely the concentration of photoexcited molecules, meaning that the raw data first should be integrated before a fit can be physically meaningful.

Another important aspect of the proposed analysis is the heavy-tail fit equation itself, which hosts 5 different fit parameters, each with a physical meaning. In an alternative embodiment, the heavy-tail fit equation can host fewer or additional fit parameters. The first three are used for any relaxation fit, namely the time scale τ of the relaxation, the amplitude f_{Δ} of the relaxation, and the asymptotic value f_{∞}. The remaining two fit parameters are unique to the proposed method, and include a mixing parameter or molecularity m ratio of the initial minority concentration to the majority concentration m=f_{Δ}/(f_{∞}+f_{Δ}), and the anomalous diffusion exponent β.

Starting with a majority reactant concentration f(t) and a minority reactant concentration g(t), the following differential equation holds for a mixed bimolecular reaction:

f′(t)=g′(t)=−k(t)f(t)g(t) Equation 1:

One can then re-express the majority and minority concentrations in terms of its asymptotic value f_{∞} and the transient component f_{Δ}(t) of the majority reactant as follows:

f(t)=f_{Δ}(t)+f_{∞} Equation 2:

g(t)=f_{Δ}(t) Equation 3:

With the minority-to-majority reactant ratio m set to:

m=f_{Δ}(0)/[f_{Δ}(0)+f_{∞}], Equation 4:

and a time-dependent anomalous diffusion reaction rate set to:

$$k ( t ) = \frac{β}{τ} {( \frac{t}{τ} )}^{β - 1} . \qquad Equation 5$$

With anomalous exponent β, the final differential equation governing the relaxation can be written as follows:

$${f}^{′} ( t ) = - \frac{β}{τ} {( \frac{t}{τ} )}^{β - 1} \{ ( 1 - m ) f ( t ) + \frac{{mf}^{2} ( t )}{[ {f}_{Δ} ( 0 ) + {f}_{∞} ]} \} \qquad Equation 6$$

Upon integration, the final heavy-tail fitting equation becomes:

$$f ( t ) = {f}_{Δ} ( 0 ) \frac{1 - m}{{e}^{( 1 - m ) {( t / τ )}^{β}} - m} + {f}_{∞} \qquad Equation 7$$

Another unique aspect of the proposed analysis is the universality of the single fit function. In standard fitting software, it is up to the user to decide if they wish to fit with a single exponential OR a multi-exponential OR a stretched exponential OR a power-law tail. The proposed heavy-tail fit equation removes the subjectivity of the user since it fits a single equation which either encompasses all of the above fitting options or provides superior fits with fewer fit parameters. This eliminates the many steps of trial and error involved for a single user, and also eliminates the divergent answers that occur when different users confronted with the same dataset arrive at quite different fit parameters.

Another unique aspect of the proposed methods and systems is the error estimation. The proposed method generates a best-fit to the experimental data according to a simulated annealing least-squares minimization to the fit curve with 4 active fit parameters plus the 5^{th} offset parameter. For three of the active fit parameters, f_{Δ}, β, and τ, the error of the fit is deduced from first transforming the parameters to a space where the variance of the fit is quadradic in the parameters—in particular re-expressing the parameter β in terms of its reciprocal T=1/β—and then applying a symmetric confidence interval around the best fit using a projection of the covariance matrix onto those parameters. For the 4th parameter m there exists no quadratic parameterization, so a higher-order curve-fit is used and the asymmetric confidence interval determined accordingly. The asymmetric confidence interval can be determined by sampling of possible solutions and calculation of the variance of each solution. The mathematical methods employed in the convergence to the best fit include simulated annealing, and the statistical analysis for the confidence interval involves a Hessian decomposition of local fit variances.

In an illustrative embodiment, software can be used to encode the methods described herein. For example, software can take a properly formatted 2-column input data file with one column for time and the 2nd column for signal amplitude, and generate as an output file a best-fit curve to that data set, listing 4 parameters plus a background value, with a confidence interval for each parameter. The software provides a mathematically objective fit to experimental data which would otherwise have allowed too much objective error with a fit-by-eye and four fit parameters. The confidence interval is a useful feature, since without the knowledge of the level of confidence surrounding a given parameter value, it is possible to misinterpret parameters as “exact” and thereby having physical meaning, when, in fact, they may not be.

In one embodiment, the software can run on a Python platform, which can be used in both Mac iOS and Microsoft operating systems. Alternatively, a different software platform may be used. A Python code inputs a 2-column data file containing the response function in column 2 versus time in column 1. The data can be entered in linear-time or log-time, and is reconfigured as amplitude versus log-time. In one embodiment, excessive datapoints in log-time can be under-sampled to reduce computational time. The data is shifted relative to its mean value to achieve a new dataset whose mean value is zero thereby determining the trivial offset parameter f_{∞}. The least-squares fit of the heavy-tail function to the input data can be achieved using a simulated annealing algorithm with the 4 remaining fit parameters. Error estimates for three of the four of the fit parameters can be deduced in a parameter space whose error is normally distributed with respect to these parameters. The tau and f-delta parameters are already normally distributed in the error, but the beta power-law exponent can be converted to T=1/beta to be normally distributed. Then a Hessian analysis function is applied to deduce the variance relative to these normally distributed values. Since the final m parameter is NOT normally distributed, the asymmetric variance of the final m parameter can be determined with an iterative convergence to the desired accuracy. Finally, the fit parameters and all of their confidence intervals (some symmetric, some asymmetric) are reported along with a best-fit curve as an output file. The output file can be used to improve the photoluminescence (or other) system.

It is noted that the physical model underlying the present methods leads to fundamentally different data interpretation which gives superior fits with fewer fit parameters. This can be attributed, at least in part to the fact that the methods integrate the data (e.g., photoluminescence data) before conducting a fit. The photoluminescence data should be integrated first before it is fit to any meaningful equation. Another advantage is the derivation of the heavy tail equation, itself. Still another advantage is the fact that the heavy-tail equation incorporates standard error (SE) and mixed bimolecular fitting into a single equation. In other methods, one would have to fit to a) exponential b) bi-exponential, c) twi-exponential, d-g) multi-exponential, h) stretched exponential, etc. In the proposed method, one can integrate the data and fit to a heavy-tail to obtain all of the desired parameters.

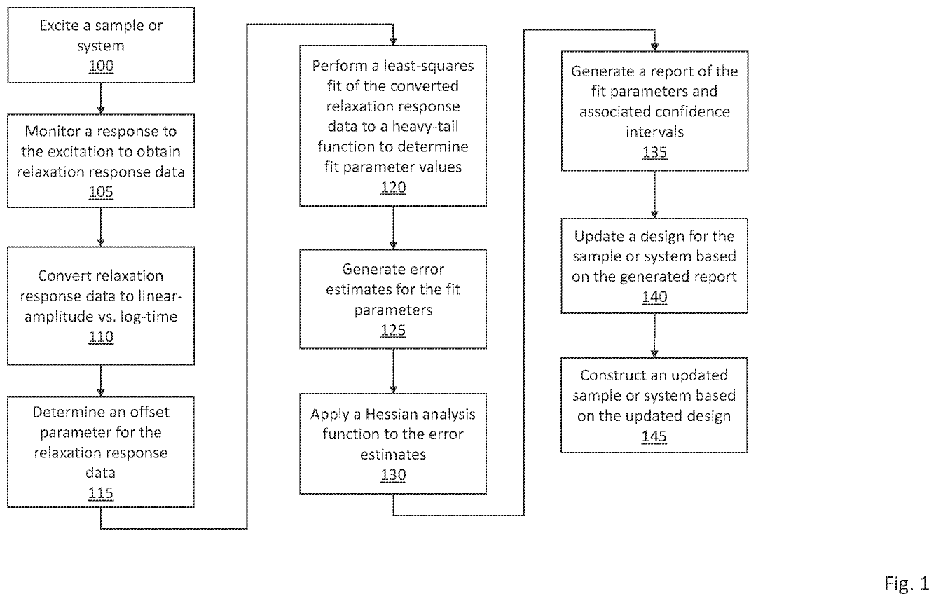

FIG. 1 is a flow diagram depicting operations performed to analyze a system and generate an updated system based on determined fit parameters and associated confidence intervals in accordance with an illustrative embodiment. In alternative embodiments, fewer, additional, and/or different operations may be performed. Additionally, the flow diagram is not meant to be limiting with respect to the order of operations performed (i.e., in alternative embodiments, the operations may be performed in a different order). In an operation 100, a sample or system is excited. The sample/system can be cells or biomarkers in cells, other biological tissues, polymers, composites, glasses, spin glasses, superconductors, etc. An excitation device can be used to perform the excitation of the sample/system. The excitation device can be application specific. Examples of the excitation device can include a laser or other light source, an electrical signal generator that directs an electric signal to the sample/system, a magnet, an arm or piston (e.g., hydraulic) that places pressure on the sample/system, etc.

In an operation 105, the system monitors a response of the sample/system to the excitation to obtain relaxation response (or excitation) data. In one embodiment, the relaxation response data can include timing data and relaxation amplitudes associated with the timing data (e.g., a relaxation amplitude can be recorded for each time increment, which can be in nanoseconds, microseconds, milliseconds, seconds, etc.). In an operation 110, the system converts the relaxation response data to linear-amplitude versus log-time data. Any conversion technique(s) may be used.

In an operation 115, the system determines an offset parameter for the relaxation response data. As discussed, the offset parameter can be determined by shifting the relaxation response data relative to its mean value to achieve a new dataset whose mean value is zero. The offset parameter can be used as a fit parameter as described herein. In an operation 120, the system performs a least-squares fit of the converted relaxation response data to a heavy-tail function to determine fit parameter values. In an illustrative embodiment, the heavy-tail function can be the function of Equation 7, described herein. The fit parameters can include the offset parameter f_{∞}, the time scale τ of the relaxation, the amplitude f_{Δ} of the relaxation, a mixing parameter or molecularity m ratio of the initial minority concentration to the majority concentration m=f_{Δ}/(f_{∞}+f_{Δ}), and an anomalous diffusion exponent β. In alternative implementations, different fit parameters may be used.

In an operation 125, the system generates error estimates for the fit parameters. For the fit parameters, f_{Δ}, β, and τ, the error of the fit can be estimated by first transforming the parameters to a space where the variance of the fit is quadradic in the parameters. For example, the parameter β can be expressed in terms of its reciprocal T=1/β, and a symmetric confidence interval can be applied around the best fit using a projection of a covariance matrix onto those parameters. For the 4th parameter m there exists no quadratic parameterization, so a higher-order curve-fit is used and the asymmetric confidence interval determined accordingly. An asymmetric confidence interval can also be determined by sampling of possible solutions and calculation of the variance of each solution. In an operation 130, the system applies a Hessian analysis function to the error estimates to determine confidence intervals for the fit parameters. The Hessian analysis can include a Hessian decomposition of local fit variances to deduce the variance relative to the normally distributed values. Since the m parameter is not normally distributed, the asymmetric variance and associated confidence interval of the final m parameter can be determined with an iterative convergence to the desired accuracy.

In an operation 135, the system generates a report of the fit parameter values and associated confidence intervals. The report includes accurate information regarding the response of the sample/system to the excitation. The data from this report is used to update a design for the sample/system in an operation 140. For example, the sample/system can altered to have a more desirable relaxation response or a relaxation response with different characteristics. In an operation 145, an updated sample/system is constructed based on the updated design, where the updated sample/system has the more desirable relaxation response or the relaxation response with different characteristics.

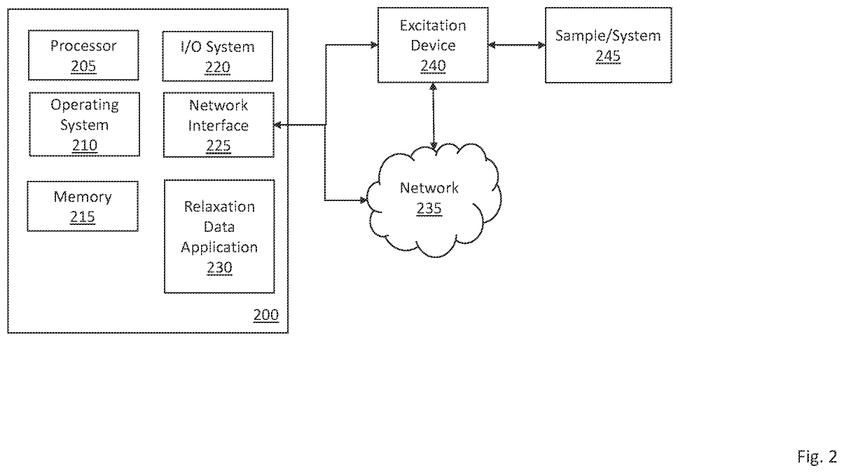

FIG. 2 is a block diagram of a computing system 200 that uses relaxation data to improve a product in accordance with an illustrative embodiment. The computing system 200 is in communication with a network 235 and an excitation device 240. The computing system 200 can communicate directly with the excitation device 240 or indirectly through the network 235. The excitation device 240 can be any type of device described herein, such as a light source, electrical signal generator, a pressure-inducing device, a magnet, etc. The excitation device 240 performs an excitation of a sample/system 245, which can be any of the samples/systems described herein. The sample/system 245 exhibits a relaxation response that is responsive to the excitation, and data related to the relaxation response is monitored and recorded by the excitation device 240, the computing system 200, or another device.

In one alternative embodiment, the computing system 200 may be incorporated into the excitation device 240. The computing system 200 includes a processor 205, an operating system 210, a memory 215, an input/output (I/O) system 220, a network interface 225, and a relaxation data application 230. In alternative embodiments, the computing system 200 may include fewer, additional, and/or different components. The components of the computing system 200 can communicate with one another via one or more buses or any other interconnect system. The computing system 200 can be any type of networked computing device, or alternatively a device that does not have network connectivity. For example, the computing system 200 can be a smartphone, a tablet, a laptop computer, a dedicated device specific to the relaxation data application, etc.

The processor 205 can be in electrical communication with and used to control any of the system components described herein. The processor 205 can be any type of computer processor known in the art, and can include a plurality of processors and/or a plurality of processing cores. The processor 205 can include a controller, a microcontroller, an audio processor, a graphics processing unit, a hardware accelerator, a digital signal processor, etc. Additionally, the processor 205 may be implemented as a complex instruction set computer processor, a reduced instruction set computer processor, an x86 instruction set computer processor, etc. The processor 205 is used to run the operating system 210, which can be any type of operating system.

The operating system 210 is stored in the memory 215, which is also used to store programs, excitation data, network and communications data, peripheral component data, the relaxation data application 2530, and other operating instructions. The memory 215 can be one or more memory systems that include various types of computer memory such as flash memory, random access memory (RAM), dynamic (RAM), static (RAM), a universal serial bus (USB) drive, an optical disk drive, a tape drive, an internal storage device, a non-volatile storage device, a hard disk drive (HDD), a volatile storage device, etc.

The I/O system 220 is the framework which enables users and peripheral devices to interact with the computing system 200. The I/O system 220 can include one or more displays (e.g., light-emitting diode display, liquid crystal display, touch screen display, etc.), a speaker, a microphone, etc. that allow the user to interact with and control the computing system 2500. The I/O system 220 also includes circuitry and a bus structure to interface with peripheral computing devices such as power sources, USB devices, data acquisition cards, peripheral component interconnect express (PCIe) devices, serial advanced technology attachment (SATA) devices, high definition multimedia interface (HDMI) devices, proprietary connection devices, etc.

The network interface 225 includes transceiver circuitry (e.g., a transmitter and a receiver) that allows the computing system to transmit and receive data to/from other devices such as the excitation device 240, other remote computing systems, servers, websites, etc. The data received from the excitation device 240 can include any information regarding a response of the sample/system 245 to an excitation performed by the excitation device 240, including time data, amplitude data, etc. The network interface 225 enables communication through the network 235, which can be one or more communication networks. The network 235 can include a cable network, a fiber network, a cellular network, a wi-fi network, a landline telephone network, a microwave network, a satellite network, etc. The network interface 225 also includes circuitry to allow device-to-device communication such as Bluetooth® communication.

The relaxation data application 230 can include software and algorithms in the form of computer-readable instructions which, upon execution by the processor 205, performs any of the various operations described herein such as receiving relaxation response data that results from an excitation, converting the received relaxation response data to linear-amplitude versus log-time data, determining an offset parameter for the relaxation response data, determining other fit parameters for the relaxation response data, determining error estimates of the fit parameters, determining confidence intervals for the fit parameters, generating a report of the fit parameters and associated confidence intervals, updating a design for the sample/system based on the generated report, etc. The relaxation data application 230 can utilize the processor 205 and/or the memory 215 as discussed above. In an alternative implementation, the relaxation data application 230 can be remote or independent from the computing system 200, but in communication therewith.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more”.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A system to improve a product based on a relaxation response, the system comprising:
a memory configured to store relaxation response data of a sample, wherein the relaxation response data includes time data and amplitude data; and
a processor operatively coupled to the memory and configured to:
convert the relaxation response data to linear-amplitude versus log-time data;
perform a least-squares fit of the converted relaxation response data to a heavy-tail function to determine one or more fit parameter values; and
update a design for the sample based at least in part on the one or more fit parameter values.

2. The system of claim 1, wherein the processor is further configured to determine an offset parameter for the relaxation response data.

3. The system of claim 2, wherein the processor is configured to:
determine a mean value of the relaxation response data; and
shift the relaxation response data relative to the mean value to create a dataset that has a zero mean value, wherein the offset parameter is based on the created dataset.

4. The system of claim 1, wherein the processor is configured to generate an error estimate for each of the one or more fit parameter values.

5. The system of claim 4, wherein to generate the error estimate of a fit parameter, the processor transforms the fit parameter to a space in which variance of a fit of the fit parameter is quadratic.

6. The system of claim 4, wherein the processor is configured to generate a confidence interval for each of the one or more fit parameter values based at least in part on the error estimate.

7. The system of claim 6, wherein the processor applies a Hessian analysis function to the error estimate to generate the confidence interval.

8. The system of claim 1, wherein the processor is configured to generate a report that includes the one or more fit parameter values and one or more confidence intervals associated with the one or more fit parameter values.

9. The system of claim 1, wherein the one or more fit parameter values includes a value of a time scale of relaxation of the sample.

10. The system of claim 1, wherein the one or more fit parameter values includes a value of an amplitude of relaxation of the sample.

11. The system of claim 1, wherein the one or more fit parameter values includes a value of a molecularity ratio of an initial minority concentration of the sample to a majority concentration of the sample.

12. The system of claim 1, wherein the one or more fit parameter values includes a value of an anomalous diffusion exponent for the sample.

13. The system of claim 1, further comprising an excitation device that excites the sample such that the sample exhibits the relaxation response that is a source of the relaxation response data.

14. A method comprising:
storing, in a memory of a computing system, relaxation response data of a sample, wherein the relaxation response data includes time data and amplitude data;
converting, by a processor of the computing system, the relaxation response data to linear-amplitude versus log-time data;
performing, by the processor, a least-squares fit of the converted relaxation response data to a heavy-tail function to determine one or more fit parameter values; and
updating a design for the sample based at least in part on the one or more fit parameter values.

15. The method of claim 14, further comprising:
determining, by the processor, a mean value of the relaxation response data;
shifting the relaxation response data relative to the mean value to create a dataset that has a zero mean value; and
determining an offset parameter for the relaxation response data based on the created dataset.

16. The method of claim 14, further comprising generating, by the processor, an error estimate for each of the one or more fit parameter values.

17. The method of claim 16, further comprising generating, by the processor, a confidence interval for each of the one or more fit parameter values based at least in part on the error estimate.

18. The method of claim 17, further comprising applying, by the processor, a Hessian analysis function to the error estimate to generate the confidence interval.

19. The method of claim 14, further comprising generating, by the processor, a report that includes the one or more fit parameter values and one or more confidence intervals associated with the one or more fit parameter values.

20. The method of claim 14, further comprising exciting, by an excitation device in communication with the computing system, the sample such that the sample exhibits a relaxation response that is a source of the relaxation response data.
